(19) United States
(12) Patent Application Publication
(10) Pub. No.: US 2012/0007593 A1
(43) Pub. Date: Jan. 12, 2012

(54) MAGNETIC SENSOR PACKAGE

(75) Inventors: Hitoshi YAMAZAKI, Niigata-ken (JP); Hideto ANDO, Niigata-ken (JP)

(73) Assignee: ALPS ELECTRIC CO., LTD., Tokyo (JP)

(21) Appl. No.: 13/239,856

(22) Filed: Sep. 22, 2011

Related U.S. Application Data
(63) Continuation of application No. PCT/JP2010/056761, filed on Apr. 15, 2010.

(30) Foreign Application Priority Data
Apr. 21, 2009 (JP) 2009-103275

(51) Int. Cl. G01B 7/30; G01R 33/02

(52) U.S. Cl. 324/207.25; 324/244

(57) ABSTRACT

In a magnetic chip package including a metal thin film, which is constituted of a metal material containing a magnetic body and is disposed on a surface of a plastic substrate opposite to the side a sensor chip is fixed, a demagnetizing field is generated in the metal thin film in a direction orthogonal to the direction of a magnetic field detected by a magnetic sensor. Specifically, the metal thin film is formed of plural metal thin sub-films, each metal thin sub-film having a rectangular shape with a length orthogonal to the direction of the magnetic field detected by the magnetic sensor larger than a width parallel to the direction of the magnetic field, and each metal thin sub-films are aligned at predetermined intervals in a direction parallel to the direction of the detected magnetic field.

### CLAIM OF PRIORITY

This application is a Continuation of International Application No. PCT/JP2010/056761 filed on Apr. 15, 2010, which claims benefit of Japanese Patent Application No. 2009-103275 filed on Apr. 21, 2009. The entire contents of each application noted above are hereby incorporated by reference.

### BACKGROUND OF THE INVENTION

1. Field of the Invention

The present invention relates to a magnetic sensor package in which a magnetic sensor chip is mounted on a plastic substrate. 2. Description of the Related Art

For example, magnetic sensors used in magnetic encoders are each packaged by mounting a magnetic sensor chip, which includes a magnetic sensor, on a plastic substrate and electrically connecting an electrode pad on the substrate front surface and the magnetic sensor chip and are each installable on an external substrate with an electrode pad on the substrate back surface, which is connected to the electrode pad on the substrate front surface. Such a magnetic sensor package includes a metal thin film on the back surface of the plastic substrate, which is the mounting surface, so as to increase the bonding strength by being bonded on the external substrate when mounted and prevent substrate deformation when mounted. A known metal thin film is made of the same film configuration (Cu plating film/Ni plating film/Au plating film) as that of the electrode pads. Japanese Unexamined Patent Application Publication No. 2000-106352 is an example of related art.

### SUMMARY OF THE INVENTION

However, it has been discovered that, since the known metal thin film contains Ni, which is a magnetic body, the leakage flux from a magnetic moving body in an encoder tends to be transmitted through the metal thin film more easily than through the magnetic sensor, and thus, decreasing the sensitivity of the magnetic sensor. When the metal thin film is made of a Cu/Au laminated film, the adhesiveness of the Cu and the Au is unsatisfactory, whereas when the metal thin film is made of only Cu, corrosion of Cu becomes a problem.

The present invention provides a magnetic sensor package in which the influence of a metal thin film, which is mounted on a substrate mounting surface and contains Ni, on the sensor sensitivity is reduced.

The present invention has been conceived by considering how to suppress the influence of a metal thin film, containing Ni, on the sensor sensitivity and by focusing on the fact that the reduction of leakage flux transmitted through a magnetic sensor can be prevented by preventing the leakage flux from entering the metal thin film due to shape anisotropy.

That is, the present invention provides a magnetic sensor chip package including a plastic substrate; a sensor chip adhesively fixed on the plastic substrate and including a magnetic sensor detecting an external magnetic field; and a metal thin film constituted of a metal material including a magnetic body disposed on a surface opposite to the surface of the plastic substrate provided with the sensor chip, wherein the metal thin film has magnetic shape anisotropy generating a demagnetizing field in a direction orthogonal to the direction of the magnetic field detected by the magnetic sensor.

Specifically, it is desirable that the metal thin film be formed of plural metal thin sub-films, each metal thin sub-film having a rectangular shape with a length orthogonal to the direction of the magnetic field detected by the magnetic sensor larger than a width parallel to the direction of the magnetic field, and each metal thin sub-films be aligned at predetermined intervals in a direction parallel to the direction of the detected magnetic field.

It is practical to form each metal thin sub-film with a film configuration of a Cu plating film, a Ni plating film, and a Au plating film, stacked in order from the plastic substrate side.

It is desirable that the magnetic sensor be paired magnetic sensors for an encoder, the paired magnetic sensors being disposed at a predetermined distance apart from each other along a direction parallel to the direction of the detected magnetic field, each magnetic sensor detecting leakage flux from a magnetic moving body dividedly magnetized with alternating N and S in the moving direction.

With the present invention, it is difficult for leakage flux to enter each metal thin sub-film because a demagnetizing field is generated in each metal thin sub-film in a direction orthogonal to the leakage magnetic field due to shape anisotropy; therefore, a magnetic sensor package that prevents reduction in leakage flux transmitted through a magnetic sensor and reduces the influence of each metal thin sub-film on the sensor sensitivity is obtained.

### BRIEF DESCRIPTION OF THE DRAWINGS

FIG. 1 is a configuration diagram illustrating, in outline, a magnetic encoder including a magnetic sensor package according to the present invention;

FIG. 2 is a perspective view of the main configuration of the magnetic sensor package in FIG. 1;

FIG. 3 is a plan view of a mounting surface (back surface) of the magnetic sensor package;

FIG. 4 is a schematic sectional view of the magnetic sensor package in a mounted state;

FIG. 5 is a plan view of a mounting surface of a magnetic sensor package not including metal thin films (first comparative example); and

FIG. 6 is a plan view of a mounting surface of a magnetic sensor package having a metal thin layer with a width larger than the length (second comparative example).

### DESCRIPTION OF THE PREFERRED EMBODIMENTS

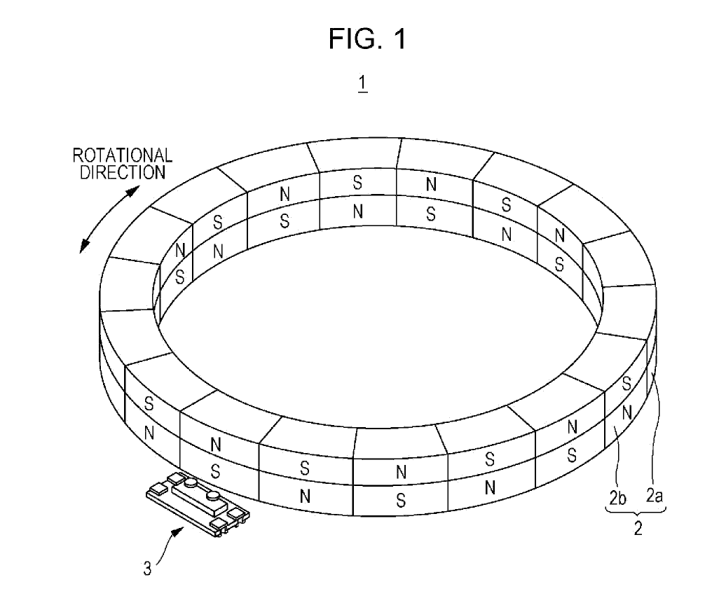

FIG. 1 illustrates a magnetic encoder according to an embodiment of the present invention. The magnetic encoder 1 includes a magnetic moving body 2, which is rotationally driven, and a magnetic sensor package 3 having magnetic sensors 30, which detect leakage magnetic field Hex from the magnetic moving body 2. The magnetic moving body 2 is an axial type in which two permanent magnets 2a and 2b, which are dividedly magnetized into alternating Ns and Ss along the circumferential direction, are stacked and bonded on each other such that the Ns and Ss alternate also in a rotation direction of the magnetic moving body 2. The magnetic sensor package 3 is disposed adjacent to the permanent magnet 2b with a predetermined gap provided therebetween on the lower side of the magnetic moving body 2, i.e., at substantially the same height as the permanent magnet 2b. When the magnetic moving body 2 rotates, the N and S poles of the permanent magnet 2b alternately passes by the magnetic sensor package 3, causing the direction of the leakage magnetic field Hex from the magnetic moving body 2 to be inverted and the output of the magnetic sensors 30 to be switched. The position of the magnetic sensor package 3 may be upward or downward with respect to the magnetic moving body 2.

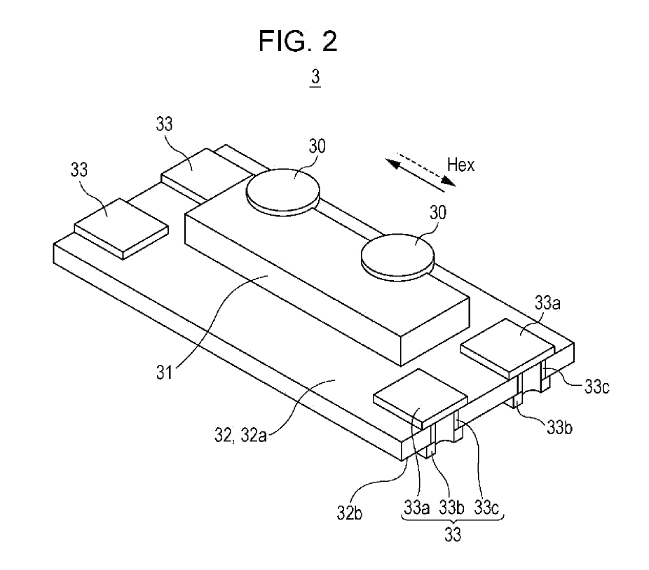

FIG. 2 is a perspective view of the configuration of the magnetic sensor package 3 according to the present invention. The magnetic sensor package 3 includes a sensor chip 31, which includes the magnetic sensors 30, and a plastic substrate 32 on which the sensor chip 31 is adhesively fixed to.

The paired magnetic sensors 30 are disposed at a predetermined distance in a direction parallel to the leakage magnetic field Hex from the magnetic moving body 2 such that the rotational direction of the magnetic moving body 2 can be detected. The magnetic sensors 30 are magnetic resistive elements (for example, GMR elements) or Hall elements.

The plastic substrate 32 is, for example, a glass epoxy substrate and includes a plurality of electrode pads 33 on the substrate front surface. Each of the electrode pads 33 includes a front-side electrode pad 33a, which is exposed at the substrate front surface 32a, a back-side electrode pad 33b, which is exposed at the substrate back surface 32b, and a connection conductive body 33c, which is exposed at the substrate side surface and connects the front-side and back-side electrode pads 33a and 33b. The front-side electrode pad 33a is electrically connected to the paired magnetic sensors 30. The electrode pads 33a and 33b are each formed by stacking, on the plastic substrate 32, a Cu plating film, a Ni plating film, and a Au plating film, in this order, and the connection conductive body 33c is made of Cu. The Au plating film prevents electrode corrosion, and the Ni plating film improves the adhesiveness of the Cu plating film and the au plating film.

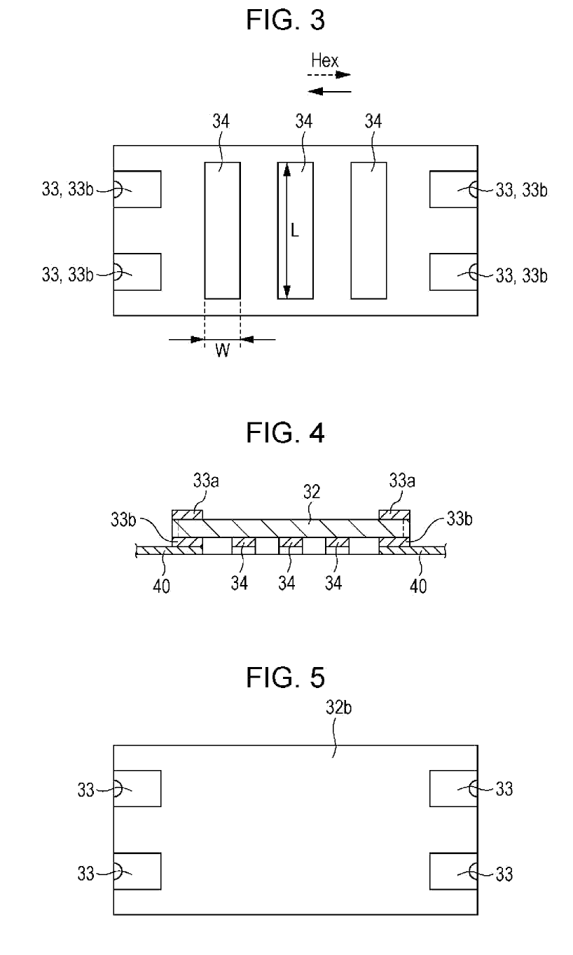

The plastic substrate 32 has metal thin films 34, containing a magnetic body (Ni), positioned on the back surface 32b, which is the surface opposite to the front surface 32a on which the sensor chip 31 is adhesively fixed. The metal thin films 34 each has a film configuration (Cu plating film/Ni plating film/Au plating film), which is the same as that of the back-side electrode pad 33b. FIG. 3 is a plan view of the back surface 32b of the plastic substrate 32. As illustrated in FIG. 3, the metal thin films 34 each has a rectangular shape in which the width W is parallel to and the length L is orthogonal to the direction of the leakage magnetic field Hex from the magnetic moving body 2 (the direction of the magnetic field detected by the magnetic sensors 30); a plurality of the metal thin films 34, which are disposed at predetermined intervals in a direction parallel to the leakage magnetic field Hex, is provided. Each of the metal thin film 34 has a length L that is larger than the width W (L>W) and has magnetic shape anisotropy, which generates a demagnetizing field in a direction orthogonal to the direction of the leakage magnetic field Hex from the magnetic moving body 2. By having such magnetic shape anisotropy, even when the metal thin film 34 contains Ni, which is a magnetic body, the leakage flux from the magnetic moving body 2 is less likely to enter the metal thin film 34, and most of it is transmitted to the sensor chip 31, preventing the sensitivity of the sensor chip 31 from being adversely affected.

FIG. 4 is a sectional view of the magnetic sensor package 3 in a mounted state. The magnetic sensor package 3 can be electrically connected to wiring parts 40 of an external substrate by the connection conductive bodies 33c via the back-side electrode pads 33b, which are connected to the front-side electrode pads 33a. The mounting surface of the magnetic sensor package 3 is the back surface 32b on which the metal thin films 34 are disposed, and when mounted, not only the back-side electrode pads 33b but also the metal thin films 34 are bonded to the external substrate, which is not illustrated. The metal thin films 34 increase the bonding strength between the external substrate and the plastic substrate 32 and function as spacers preventing deformation of the plastic substrate 32 when mounted. The metal thin films 34 also have a heat-radiating function for radiating heat when heat is emitted from the magnetic sensors 30.

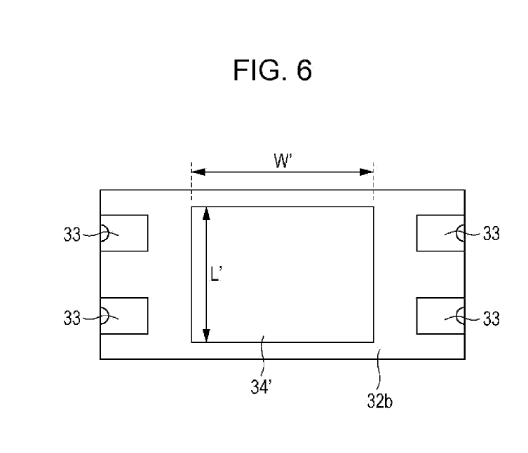

Next, with reference to Table 1, the influence of Ni, which is contained in the metal thin films 34, on the magnetic sensors 30 will be discussed. Table 1 lists the measurement results of magnetic flux density near the magnetic sensors 30 for a first embodiment in which each metal thin film 34 has a length L larger than the width W (FIG. 3), a first comparative example in which a metal thin film is not provided (FIG. 5), and a second comparative example in which a metal thin film 34′ having a length L′ smaller than the width W is provided (FIG. 6). The measurement point for the magnetic flux density was an intermediate point between the paired magnetic sensors 30 on the sensor chip 31. The film configuration of each metal thin film 34 was Cu (40 (μm)/Ni (7 (μm)/Au (0.3 (μm).

TABLE 1

| | | First | Second |
|---|---|---|---|
| Magnetic flux | First | comparative | comparative |
| density (mT) | embodiment | example | example |
| Bx | 13.649 | 14.103 | 11.069 |
| By | 0.017 | 0.027 | 0.021 |
| Bz | 0.015 | 0.004 | 0.027 |

In Table 1, Bx represents the magnetic flux density in a direction parallel to the leakage magnetic field Hex (width W direction of the metal thin films), By represents the magnetic flux density in a direction orthogonal to the leakage magnetic field Hex (length L direction of the metal thin films), and Bz represents the magnetic flux density in the thickness direction of the plastic substrate 32.

Referring to Table 1, the magnetic flux density By in a direction orthogonal to the leakage magnetic field Hex and the magnetic flux density Bz in the thickness direction of the plastic substrate 32 were substantially zero, and thus, the magnetic flux density Bx in a direction parallel to the leakage magnetic field Hex contributes to the sensitivity of the magnetic sensors 30. A large magnetic flux density Bx increases the sensitivity of the magnetic sensors 30. With the second comparative example including the metal thin film 34′, having a width W larger than the length L′, the magnetic flux density Bx is reduced by approximately 3 mT compared with the first comparative example not including a metal thin film. In contrast, with the first embodiment including the rectangular metal thin films 34, each having a length L larger than the width W, the magnetic flux density Bx is reduced by approximately 0.5 mT compared with the first comparative example, but the reduction level is smaller than that of the second comparative example; it is apparent that the influence on the magnetic sensors 30 is suppressed.

According to the present invention, since the rectangular metal thin films 34, each of which has a length L orthogonal to the leakage magnetic field Hex from the magnetic moving body 2 larger than the width W parallel to the leakage magnetic field Hex, are provided, a demagnetizing field is generated in the metal thin films 34 in a direction orthogonal to the leakage magnetic field Hex due to shape magnetic anisotropy, and, thus, it is difficult for the leakage flux from the magnetic moving body 2 to pass through the metal thin films 34 due to the demagnetizing field. Consequently, most of the leakage flux from the magnetic moving body 2 is transmitted to the magnetic sensors 30, preventing the sensitivity of the magnetic sensors 30 to be adversely affected even through the metal thin films 34 containing a magnetic body are provided.

In the above, a magnetic sensor package for an encoder according to an embodiment of the present invention has been described; in addition to a magnetic sensor package for an encoder, the present invention may be applied to any typical magnetic sensor package in which a metal thin film containing a magnetic body is disposed on a mounting surface of a plastic substrate.

The present invention may be applied to a magnetic sensor package in which a metal thin film containing a magnetic body is disposed on a mounting surface of a plastic substrate.

What is claimed is:

1. A magnetic sensor chip package comprising:
a plastic substrate;
a sensor chip adhesively fixed on the plastic substrate and including a magnetic sensor detecting an external magnetic field; and
a metal thin film constituted of a metal material including a magnetic body disposed on a surface opposite to the surface of the plastic substrate provided with the sensor chip,
wherein the metal thin film has magnetic shape anisotropy generating a demagnetizing field in a direction orthogonal to the direction of the magnetic field detected by the magnetic sensor.

2. The metal sensor chip package according to claim 1, wherein
the metal thin film is in a rectangular shape with a longitudinal length orthogonal to a direction of the external magnetic field, the longitudinal length being larger than a width length parallel to the direction of the external magnetic field, and
the metal thin film constitutes a member of plural metal thin films substantially identical with each other, the plural metal thin films being aligned in a direction parallel to the external magnetic field at predetermined intervals.

3. The metal sensor chip package according to claim 1, wherein the metal thin film includes, in order from the plastic substrate side, a Cu plating film, a Ni plating film, and a Au plating film.

4. The metal sensor chip package according to claim 1, wherein
the magnetic sensor is configured with paired magnetic sensors for an encoder, the paired magnetic sensors being disposed at a predetermined distance apart from each other along a direction parallel to the direction of the detected magnetic field, each magnetic sensor detecting leakage flux from a magnetic moving body dividedly magnetized with alternating N and S in the moving direction.
